(19) United States
(12) Patent Application Publication
(10) Pub. No.: US 2023/0234520 A1
(43) Pub. Date: Jul. 27, 2023

(54) WIRE HARNESS UNIT

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Takeo MARUCHI, Yokkaichi-shi (JP); Masanori KUWAHARA, Yokkaichi-shi (JP); Yuichi KIMOTO, Yokkaichi-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 18/007,959

(22) PCT Filed: May 27, 2021
(86) PCT No.: PCT/JP2021/020243

§ 371 Date: Dec. 2, 2022

(30) Foreign Application Priority Data
Jun. 8, 2020 (JP) 2020-099407

(51) Int. Cl. B60R 16/02; H02G 3/03

(52) U.S. Cl. CPC B60R 16/0207; H02G 3/03

(57) ABSTRACT

A wire harness unit including: a conduction path that conducts electricity between in-vehicle devices; and a cooling tube that cools the conduction path, wherein: the conduction path has a hollow tubular conductor having conductivity, and a first insulating layer covered by the tubular conductor, the cooling tube is configured to circulate a refrigerant therethrough and is separate from the tubular conductor, and the cooling tube passes through the first insulating layer.

### BACKGROUND

The present disclosure relates to a wire harness unit.

Conventionally, wire harnesses that are installed in vehicles such as hybrid vehicles and electric vehicles electrically connect a plurality of electrical devices. Also, with electric vehicles, a wire harness connects the vehicle to a ground facility, and the ground facility charges a power storage device installed in the vehicle. The amount of heat generated by the wire harness increases due to an increase in the voltage that is supplied by the wire harness. Configurations for cooling wire harnesses have thus been proposed.

For example, JP 2019-115253A discloses a wire harness that includes a coated wire, an inner tube that covers the coated wire and an outer tube that covers the inner tube with a predetermined interval therebetween, and in which a circulation channel for a refrigerant is formed between the inner tube and the outer tube. The circulation channel is formed by the inner and outer tubes that are separate from the coated wire, and the coated wire is disposed radially on the inner side of the circulation channel.

### SUMMARY

Incidentally, with the wire harness of JP 2019-115253A, the circulation channel (channel through which the refrigerant circulates) is disposed on the outer side of the coated wire, and thus the refrigerant is at a distance from the central portion of the coated wire which is the heat source, leaving room for improvement in terms of cooling efficiency of the coated wire.

An exemplary aspect of the disclosure provides a wire harness unit that enables cooling efficiency to be improved.

A wire harness unit according to one mode of the present disclosure includes a conduction path that conducts electricity between in-vehicle devices, and a cooling tube that cools the conduction path, the conduction path having a hollow tubular conductor having conductivity, and a first insulating layer covered by the tubular conductor, the cooling tube is configured to circulate a refrigerant therethrough and is separate from the tubular conductor, and the cooling tube passing through the first insulating layer.

With a wire harness unit which is one mode of the present disclosure, cooling efficiency can be improved.

### BRIEF DESCRIPTION OF THE DRAWINGS

FIG. 1 is a schematic diagram showing a vehicle in which a wire harness unit in one embodiment is routed.

FIG. 2 is a schematic diagram of the wire harness unit.

FIG. 3 is a partial cross-sectional view showing an outline of the wire harness unit.

FIG. 4 is a cross-sectional view of the wire harness unit.

FIG. 5 is an illustrative diagram showing the connection between a tubular conductor and terminals.

FIG. 6 is a partial cross-sectional view showing an outline of the wire harness unit of an example modification.

### DETAILED DESCRIPTION OF EMBODIMENTS

### Description of Embodiments of Disclosure

Initially, embodiments of the present disclosure will be enumerated and described.

[1] A wire harness unit of the present disclosure includes a conduction path that conducts electricity between in-vehicle devices, and a cooling part that cools the conduction path, the conduction path having a hollow tubular conductor having conductivity, and a first insulating layer covered by the tubular conductor, the cooling part having a cooling tube that is configured to circulate a refrigerant therethrough and is separate from the tubular conductor, and the cooling tube passing through the first insulating layer.

According to this configuration, due to the cooling tube through which the cooling medium circulates passing through the first insulating layer, the cooling medium can be supplied to the inner side of the tubular conductor covering the outer peripheral surface of the first insulating layer. The tubular conductor can thus be cooled from the inside, and cooling efficiency can be improved.

[2] Preferably, the tubular conductor is a first braided member formed by braiding metal wire strands.

According to this configuration, the tubular conductor which is a first braided member formed by braiding metal wire strands has flexibility, thus enabling dimensional tolerance of the conduction path to be taken up. Furthermore, such a configuration also acts as a countermeasure against shaking that occurs when the vehicle is travelling.

[3] Preferably, the wire harness unit includes an electromagnetic shielding member covering the cooling tube and the conduction path, the electromagnetic shielding member is a second braided member formed by braiding metal wire strands, the first insulating layer has a first exposed portion exposed from the tubular conductor, the first exposed portion covers the cooling tube, and the cooling tube passes through the second braided member.

According to this configuration, shieldability for suppressing emission of electromagnetic noise from the conduction path and assembly workability of the cooling part can both be achieved. Due to the first exposed portion of the first insulating layer, the cooling tube can be prevented from contacting the tubular conductor which is the first braided member.

[4] Preferably, the wire harness unit includes an electromagnetic shielding member covering the cooling tube and the conduction path, the electromagnetic shielding member is a second braided member formed by braiding metal wire strands, the first insulating layer has a first exposed portion exposed from the tubular conductor, the first exposed portion covers the cooling tube, and the first exposed portion and the cooling tube pass through the second braided member.

According to this configuration, shieldability for suppressing emission of electromagnetic noise from the conduction path and assembly workability of the cooling part can both be achieved. Due to the first exposed portion of the first insulating layer, the cooling tube can be prevented from contacting the tubular conductor which is the first braided member and the electromagnetic shielding member which is the second braided member.

[5] Preferably, the conduction path has a terminal and a second insulating layer covering an outer peripheral surface of the tubular conductor, the tubular conductor has a second exposed portion exposed from the second insulating layer, the second exposed portion is electrically connected to the terminal, and the second exposed portion branches away from the first exposed portion and is covered by the electromagnetic shielding member.

According to this configuration, shieldability for suppressing emission of electromagnetic noise from the conduction path and assembly workability of the cooling part can both be achieved.

[6] Preferably, the wire harness unit includes a covering member covering the second exposed portion.

According to this configuration, contact between the second exposed portion of the tubular conductor and the electromagnetic shielding member can be prevented.

[7] Preferably, the wire harness unit includes an exterior member covering the conduction path, the exterior member has a tubular exterior member and a grommet connected to an end portion of the tubular exterior member, and the cooling tube passes through the grommet.

According to this configuration, the cooling tube is led outside through a grommet, thus enabling deterioration in the water sealing performance of the wire harness unit to be suppressed.

### Detailed Description of Embodiments of Disclosure

Specific examples of a wire harness unit of the present disclosure will be described below with reference to the drawings. In the individual diagrams, parts of the configuration may be shown in an exaggerated or simplified manner, for convenience of description. Also, the dimensional ratios of various portions may differ between the diagrams. Herein, “parallel” and “orthogonal” include not only strictly parallel and orthogonal but also generally parallel and orthogonal within a range that achieves the operation and effects of the present embodiment. Note that the present disclosure is not limited to these illustrative examples and is defined by the claims, and all changes that come within the meaning and range of equivalency of the claims are intended to be embraced therein.

### Schematic Configuration of Wire Harness Unit 10

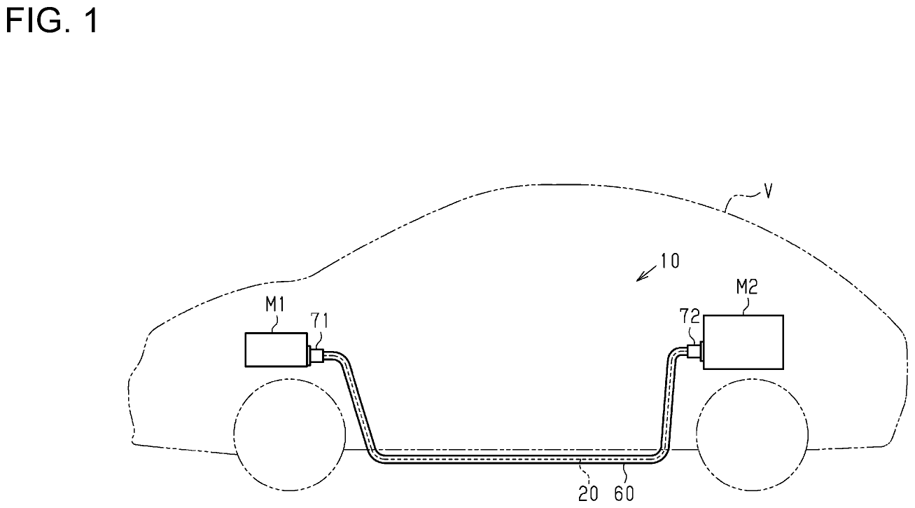

A wire harness unit 10 shown in FIG. 1 electrically connects two in-vehicle devices installed in a vehicle V. The vehicle V is, for example, a hybrid vehicle or an electric vehicle. The wire harness unit 10 has a conduction path 20 that electrically connects an in-vehicle device M1 and an in-vehicle device M2, and an exterior member 60 (exterior cover) that covers the conduction path 20. The conduction path 20 is, for example, routed from the in-vehicle device M1 to the in-vehicle device M2 in a manner whereby part thereof in the length direction passes under the floor of the vehicle V. As examples of the in-vehicle device M1 and the in-vehicle device M2, the in-vehicle device M1 is an inverter installed toward the front of the vehicle V, and the in-vehicle device M2 is a high voltage battery installed more rearward in the vehicle V than the in-vehicle device M1. The in-vehicle device M1 serving as an inverter is, for example, connected to a motor (not shown) for driving wheels that serves as a power source for vehicle travel. The inverter generates AC power from DC power of the high voltage battery and supplies the AC power to the motor. The in-vehicle device M2 serving as a high voltage battery is, for example, a battery capable of supplying a voltage of 100 volts or more. Specifically, the conduction path 20 of the present embodiment constitutes a high voltage circuit that enables transmission of a high voltage between the high voltage battery and the inverter.

### Schematic Configuration of Wire Harness Unit 10

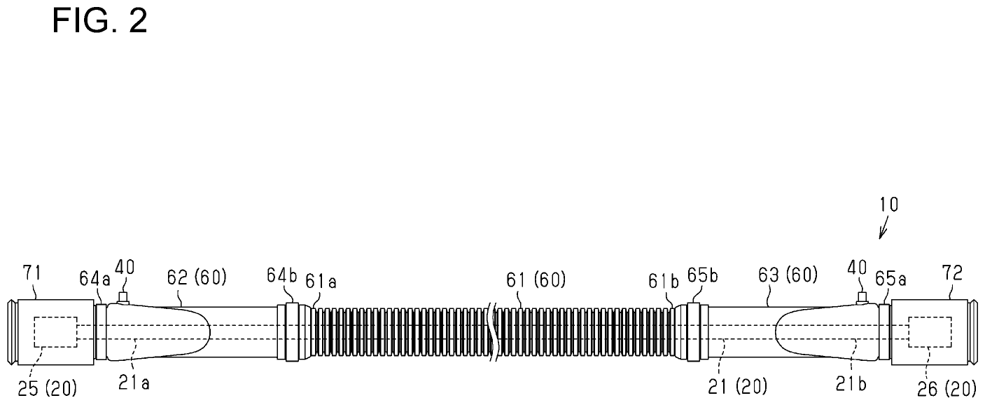

As shown in FIGS. 2, 3 and 4, the wire harness unit 10 has two conduction paths 20, two cooling tubes 40, an electromagnetic shielding member 50 (electromagnetic shield), the exterior member 60, and connectors 71 and 72.

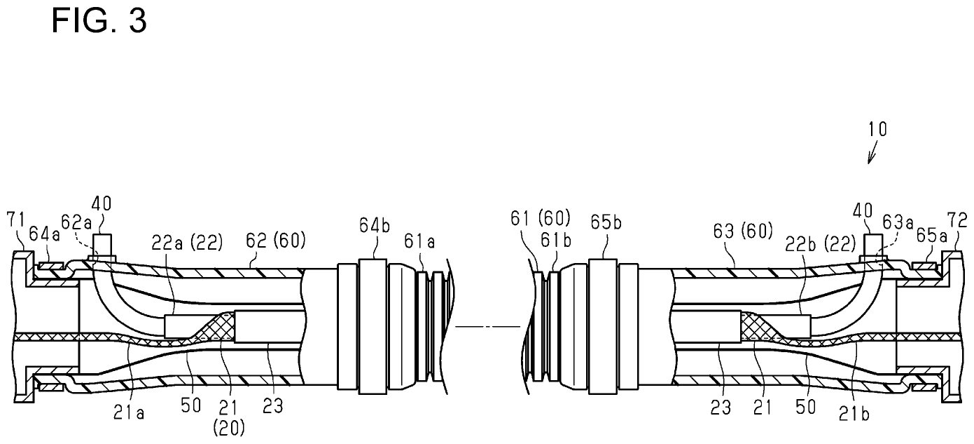

As shown in FIGS. 3, 4 and 5, each conduction path 20 has a tubular conductor 21, a first insulating layer 22, a second insulating layer 23, and terminals 25 and 26.

The tubular conductor 21 has conductivity and an internally hollow structure. The tubular conductor 21 is a first braided member formed by braiding metal wire strands, for example. A plated layer such as a tin-plated layer, for example, may be formed on the surface of the metal wire strands. The material of the tubular conductor 21 is a copper-based or aluminum-based metal material, for example. The tubular conductor 21 is formed into a shape that corresponds to the routing path of the wire harness unit 10 shown in FIG. 1. The tubular conductor 21 is subjected to a bending process by a pipe bender (pipe bending machine).

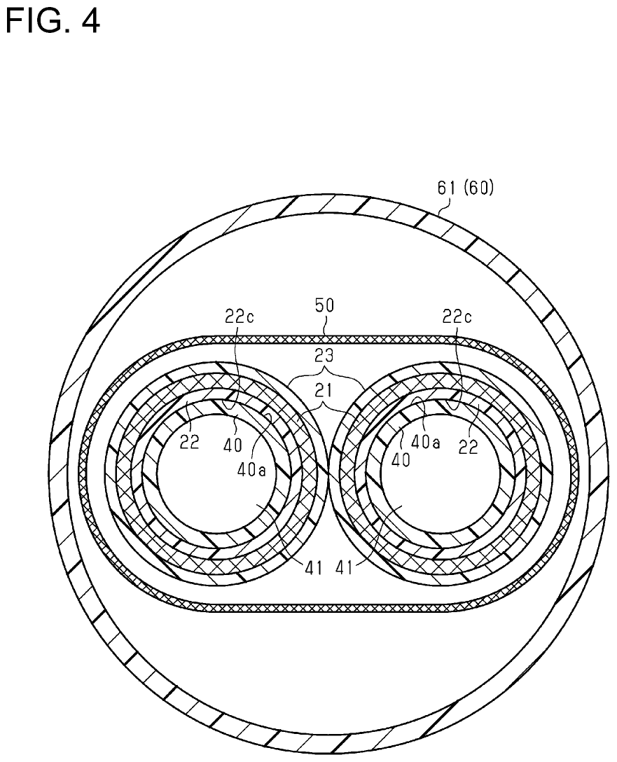

FIG. 4 shows a cross-section in which the wire harness unit 10 is cut by a plane orthogonal to the length direction of the wire harness unit 10. In FIG. 4, the length direction of the tubular conductor 21 is the depth direction as it appears in FIG. 4. The cross-sectional shape (i.e., transverse sectional shape) obtained by cutting the tubular conductor 21 by a plane perpendicular to the length direction of the tubular conductor 21, that is, the axial direction of the tubular conductor 21 which is the direction in which the tubular conductor 21 extends, is annular, for example. Note that the cross-sectional shape of the tubular conductor 21 can be any shape. Also, in the cross-sectional shape of the tubular conductor 21, the outer peripheral shape and the inner peripheral shape may differ from each other. Also, the cross-sectional shape may differ in the length direction of the tubular conductor 21.

The first insulating layer 22 has an internally hollow structure and has flexibility. Also, the first insulating layer 22 has insulating properties. The outer peripheral surface of the first insulating layer 22 is covered by the tubular conductor 21. The first insulating layer 22 is constituted by an insulating material such as a synthetic resin, for example. As the material of the first insulating layer 22, a silicone resin or a synthetic resin whose main component is a polyolefin resin such as crosslinked polyethylene or crosslinked polypropylene can be used, for example. As the material of the first insulating layer 22, one material can be used on its own, or two or more materials can be used in combination as appropriate. The first insulating layer 22 can be formed by extrusion molding (extrusion coating) performed on the tubular conductor 21, for example.

The second insulating layer 23 covers the outer peripheral surface of the tubular conductor 21 around the entire circumference in the circumferential direction, for example. The second insulating layer 23 has flexibility. Also, the second insulating layer 23 has insulating properties. The second insulating layer 23 is constituted by an insulating material such as a synthetic resin, for example. As the material of the second insulating layer 23, a silicone resin or a synthetic resin whose main component is a polyolefin resin such as crosslinked polyethylene or crosslinked polypropylene can be used, for example. As the material of the second insulating layer 23, one material can be used on its own, or two or more materials can be used in combination as appropriate. The second insulating layer 23 can be formed by extrusion molding (extrusion coating) performed on the tubular conductor 21, for example.

As shown in FIG. 3, the first insulating layer 22 has exposed portions 22a and 22b that are respectively exposed from the tubular conductor 21 at either end of the first insulating layer 22 in the length direction. The exposed portions 22a and 22b cover the cooling tube 40.

As shown in FIG. 3, the tubular conductor 21 has exposed portions 21a and 21b that are exposed from the second insulating layer 23 at either end of the tubular conductor 21 in the length direction.

As shown in FIG. 3, the exposed portion 21a extends to the connector 71. The exposed portion 21b extends to the connector 72.

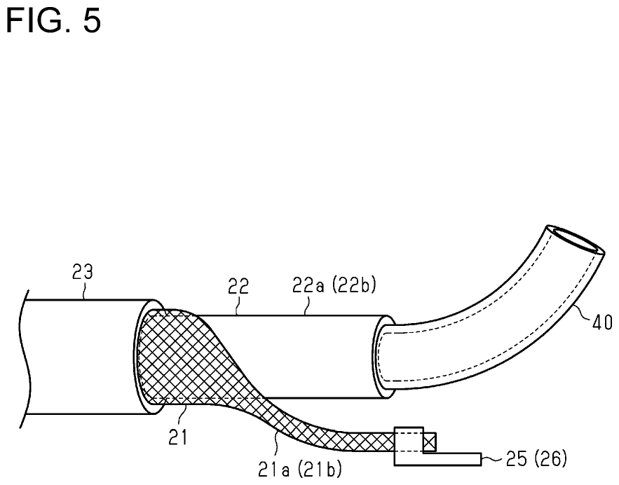

FIG. 5 is an illustrative diagram showing the connection between the tubular conductor and the terminals. Note that, in FIG. 5, the members of the conduction path 20 shown on the left side of FIGS. 2 and 3 are indicated by reference numerals without parentheses, and the members shown on the right side of FIGS. 2 and 3 are indicated by reference numerals in parentheses.

The terminal 25 is held in the connector 71 shown in FIGS. 1 and 2, and is connected to the in-vehicle device M1. The terminal 25 is connected to the distal end of the exposed portion 21a of the tubular conductor 21. For example, the terminal 25 has a pair of crimping pieces, and is crimped to the distal end of the exposed portion 21a by these crimping pieces. The terminal 26 is held in the connector 72 shown in FIGS. 1 and 2, and is connected to the in-vehicle device M2. The terminal 26 is connected to the distal end of the exposed portion 21b of the tubular conductor 21. For example, the terminal 26 has a pair of crimping pieces, and is crimped to the distal end of the exposed portion 21b by these crimping pieces.

As shown in FIGS. 3 and 4, the cooling tube 40 passes through the first insulating layer 22. The cooling tube 40 is formed in a hollow shape. The cooling tube 40 is superior in flexibility to the tubular conductor 21. In other words, the tubular conductor 21 is superior in rigidity to the cooling tube 40.

As shown in FIG. 4, in the present embodiment, an outer peripheral surface 40a of the cooling tube 40 is in contact with an inner peripheral surface 22c of the first insulating layer 22. Note that a resin material such as a bonding agent or a pressure-sensitive adhesive may be interposed between the outer peripheral surface 40a of the cooling tube 40 and the inner peripheral surface 22c of the first insulating layer 22. As the interposed resin material, a material having good thermal conductivity can be used. The material of the cooling tube 40 is a resin material having flexibility, such as PP (polypropylene), PVC (polyvinyl chloride) or crosslinked PE (polyethylene).

The cooling medium 41 is supplied inside the cooling tube 40. The cooling medium 41 is, for example, any of various types of fluids such as a liquid like water or antifreeze, a gas or a gas-liquid two-phase flow consisting of a mixture of a gas and a liquid. The cooling medium 41 is supplied by a pump not shown. The cooling tube 40 constitutes part of a circulation channel that circulates the cooling medium 41. The circulation channel includes, for example, the pump described above and a heat dissipation part. The pump pumps the cooling medium into the cooling tube 40. The cooling medium 41 supplied to the cooling tube 40 exchanges heat with the tubular conductor 21 located on the outer side of the cooling tube 40. The heat dissipation part dissipates the heat of the cooling medium 41 whose temperature has risen due to the heat exchange externally and cools the cooling medium 41. The cooled cooling medium 41 is again pumped by the pump to the cooling tube 40. The cooling tube 40 constitutes a cooling part that cools the tubular conductor 21 with the cooling medium 41 that circulates in this way.

As shown in FIGS. 3 and 4, the electromagnetic shielding member 50 covers two conduction paths 20. The electromagnetic shielding member 50 is a second braided member formed by braiding metal wire strands into a tubular shape. The electromagnetic shielding member 50 has shieldability. Also, the electromagnetic shielding member 50 has flexibility. As shown in FIG. 3, one end of the electromagnetic shielding member 50 is connected to the connector 71, and the other end of the electromagnetic shielding member 50 is connected to the connector 72. Accordingly, the electromagnetic shielding member 50 covers the entire length of the conduction path 20 that transmits a high voltage. External emission of electromagnetic noise that is generated from the conduction paths 20 is thereby suppressed.

The exterior member 60 covers the conduction paths 20 and the electromagnetic shielding member 50. The cooling tubes 40 pass through the first insulating layer 22 of the respective conduction paths 20. The first insulating layer 22 is covered by the tubular conductor 21. Accordingly, the cooling tube 40 can also be said to pass through the tubular conductor 21. Also, the exterior member 60 covers the conduction paths 20, the electromagnetic shielding member 50 and at least part of the cooling tubes 40.

The exterior member 60 has a tubular exterior member 61 (tubular exterior) and grommets 62 and 63 respectively connected to a first end portion 61a and a second end portion 61b of the tubular exterior member 61.

The tubular exterior member 61 is, for example, provided so as to cover part of the outer periphery of the tubular conductor 21 in the length direction. The tubular exterior member 61 has, for example, a tubular shape in which both ends in the length direction of the tubular conductor 21 are open. The tubular exterior member 61 is, for example, provided so as to enclose the outer periphery of the plurality of tubular conductors 21 around the entire circumference in the circumferential direction. The tubular exterior member 61 of the present embodiment is formed in a cylindrical shape. The tubular exterior member 61 has, for example, a bellows structure in which an annular raised portion and an annular recessed portion are alternately connected continuously in the axial direction (length direction) in which the center axis of the tubular exterior member 61 extends. As the material of the tubular exterior member 61, a resin material having conductivity or a resin material not having conductivity can be used, for example. As the resin material, a synthetic resin such as polyolefin, polyamide, polyester or ABS resin can be used, for example. The tubular exterior member 61 of the present embodiment is a corrugated tube made of synthetic resin.

The grommet 62 is formed in a generally tubular shape. The grommet 62 is made of rubber, for example. The grommet 62 is formed so as to bridge between the connector 71 and the tubular exterior member 61. The grommet 62 is fastened and fixed by a fastening band 64a so as to be in intimate contact with the outer surface of the connector 71. Also, the grommet 62 is fastened and fixed by a fastening band 64b so as to be in intimate contact with the outer side of the first end portion 61a of the tubular exterior member 61. A through hole 62a that passes through the grommet 62 is formed in the grommet 62. The through hole 62a communicates between the inside and outside of the grommet 62.

In the present embodiment, two through holes 62a are formed in the grommet 62, and the cooling tubes 40 are inserted through the through holes 62a. The through holes 62a are formed so as to be in intimate contact with the outer peripheral surface of the cooling tubes 40 that are inserted therethrough. As shown in FIG. 3, the cooling tubes 40 pass through the exposed portions 21a and the electromagnetic shielding member 50, and are led outside the grommet 62 via the through holes 62a in the grommet 62.

The grommet 63 is formed in a generally tubular shape. The grommet 63 is made of rubber, for example. The grommet 63 is formed so as to bridge between the connector 72 and the tubular exterior member 61. The grommet 63 is fastened and fixed by a fastening band 65a so as to be intimate contact with the outer surface of the connector 72. Also, the grommet 63 is fastened and fixed by a fastening band 65b so as to be in intimate contact with the outer side of the second end portion 61b of the tubular exterior member 61. A through hole 63a that passes through the grommet 63 is formed in the grommet 63. The through hole 63a communicates between the inside and outside of the grommet 63.

In the present embodiment, two through holes 63a are formed in the grommet 63, and the cooling tubes 40 are inserted through the through holes 63a. The through holes 63a are formed so as to be in intimate contact with the outer peripheral surface of the cooling tubes 40 that are inserted therethrough. As shown in FIG. 3, the cooling tubes 40 pass through the exposed portions 21b and the electromagnetic shielding member 50, and are led outside the grommet 63 via the through holes 63a in the grommet 63.

### Operation

Next, the operation of the wire harness unit 10 of the present embodiment will be described.

The wire harness unit 10 includes the conduction path 20 that conducts electricity between the in-vehicle devices M1 and M2, and the cooling tube 40 constituting the cooling part that cools the conduction path 20. The conduction path 20 has the hollow tubular conductor 21 having conductivity and the first insulating layer 22 covered by the tubular conductor 21. The cooling tube 40 is configured to circulate refrigerant therethrough and is separate from the tubular conductor 21. Also, the cooling tube 40 passes through the first insulating layer 22.

The cooling medium 41 is supplied to the cooling tube 40. The first insulating layer 22 through which the cooling tube 40 passes is covered by the tubular conductor 21. Accordingly, the cooling tube 40 passes through the tubular conductor 21 and circulates the cooling medium 41 on the inner side of the tubular conductor 21. The tubular conductor 21 is thus cooled through heat exchange between the tubular conductor 21 and the cooling medium 41 that circulates through the cooling tube 40. In this way, the tubular conductor 21 can be cooled from the inner side.

The tubular conductor 21 has a longer outer peripheral length, compared with a single core wire having a solid structure or a twisted wire formed by twisting together a plurality of metal wire strands having the same cross-sectional area. That is, the tubular conductor 21 has a larger area on the outer peripheral side, compared with a single core wire or a twisted wire. Accordingly, heat can be dissipated externally from a larger area, thus enabling heat dissipation to be improved.

The tubular conductor 21 of the conduction path 20 is a braided member formed by braiding metal wire strands, and has the exposed portions 21a and 21b exposed from the second insulating layer 23. Distal ends of the exposed portions 21a and 21b are respectively connected to the terminals 25 and 26 fixed to the connectors 71 and 72. The exposed portions 21a and 21b are superior in flexibility to the second insulating layer 23. Accordingly, dimensional tolerance of the conduction path 20 can be taken up. Also, when the vehicle V vibrates, positional shift between the components caused by this vibration can be absorbed. Accordingly, the load that is applied to the connectors 71 and 72 and the terminals 25 and 26 can be reduced.

The tubular conductor 21 of the present embodiment is a first braided member formed by braiding metal wire strands into a tubular shape. The cooling tube 40 can thus be led out through the exposed portions 21a and 21b of the tubular conductor 21, partway along the exposed portions 21a and 21b. The cooling tube 40 can thereby be easily led outside the wire harness unit 10, and the constituent members for circulating the cooling medium 41 can be easily connected to the cooling tube 40.

The electromagnetic shielding member 50 covers two conduction paths 20. The electromagnetic shielding member 50 is a second braided member formed by braiding metal wire strands into a tubular shape. External emission of electromagnetic noise that is generated from the conduction paths 20 can thus be suppressed. Also, the cooling tubes 40 can thus be led out through the electromagnetic shielding member 50, partway along the electromagnetic shielding member 50. The cooling tubes 40 can thereby be easily led outside the wire harness unit 10, and the constituent members for circulating the cooling medium 41 can be easily connected to the cooling tubes 40.

The wire harness unit 10 includes the exterior member 60 that covers the conduction paths 20 and at least part of the cooling tubes 40. The exterior member 60 has the tubular exterior member 61 and the grommets 62 and 63 respectively connected to the first end portion 61a and the second end portion 61b of the tubular exterior member 61. The cooling tubes 40 pass through the grommets 62 and 63. In this way, the cooling tubes 40 pass through the grommets 62 and 63 and are led outside the wire harness unit 10, thus enabling deterioration in the water sealing performance of the wire harness unit 10 to be suppressed.

As described above, according to the present embodiment, the following effects are achieved.

(1) The wire harness unit 10 includes the conduction path 20 that conducts electricity between the in-vehicle devices M1 and M2, and the cooling tube 40 constituting the cooling part that cools the conduction path 20. The conduction path 20 has the hollow tubular conductor 21 having conductivity and the first insulating layer 22 covered by the tubular conductor 21. The cooling tube 40 is configured to circulate refrigerant therethrough and is separate from the tubular conductor 21. The cooling tube 40 passes through the first insulating layer 22.

The cooling medium 41 is supplied to the cooling tube 40. The first insulating layer 22 through which the cooling tube 40 passes is covered by the tubular conductor 21. Accordingly, the cooling tube 40 passes through the tubular conductor 21 and circulates the cooling medium 41 on the inner side of the tubular conductor 21. The tubular conductor 21 is thus cooled through heat exchange with the cooling medium 41 that circulates through the cooling tube 40. In this way, the tubular conductor 21 can be cooled from the inner side.

(2) The tubular conductor 21 has a longer outer peripheral length, compared with a single core wire having a solid structure or a twisted wire formed by twisting together a plurality of metal wire strands having the same cross-sectional area. That is, the tubular conductor 21 has a larger area on the outer peripheral side, compared with a single core wire or a twisted wire. Accordingly, heat can be dissipated externally from a larger area, thus enabling heat dissipation to be improved.

(3) The tubular conductor 21 of the conduction path 20 is a braided member formed by braiding metal wire strands, and has the exposed portions 21a and 21b that are exposed from the second insulating layer 23. The distal ends of the exposed portions 21a and 21b are connected to the terminals 25 and 26 fixed to the connectors 71 and 72. The exposed portions 21a and 21b are superior in flexibility to the second insulating layer 23. Accordingly, dimensional tolerance of the conduction path 20 can be taken up. Also, when the vehicle V vibrates, positional shift between the components caused by this vibration can be absorbed. Accordingly, the load that is applied to the connectors 71 and 72 and the terminals 25 and 26 can be reduced.

(4) The exposed portions 21a and 21b of the tubular conductor 21 are braided members formed by braiding metal wire strands into a tubular shape. The cooling tube 40 can thus be led out through the exposed portions 21a and 21b, partway along the exposed portions 21a and 21b. The cooling tube 40 can thereby be easily led outside the wire harness unit 10, and the constituent members for circulating the cooling medium 41 can be easily connected to the cooling tube 40.

(5) The electromagnetic shielding member 50 covers two conduction paths 20. The electromagnetic shielding member 50 is a braided member formed by braiding metal wire strands into a tubular shape. External emission of electromagnetic noise that is generated from the conduction paths 20 can thus be suppressed. Also, the cooling tubes 40 can thus be led out through the electromagnetic shielding member 50, partway along the electromagnetic shielding member 50. The cooling tubes 40 can thereby be easily led outside the wire harness unit 10, and the constituent members for circulating the cooling medium 41 can be easily connected to the cooling tubes 40.

(6) The wire harness unit 10 includes the exterior member 60 that covers the conduction paths 20 and at least part of the cooling tubes 40. The exterior member 60 has the tubular exterior member 61 and the grommets 62 and 63 respectively connected to the first end portion 61a and the second end portion 61b of the tubular exterior member 61. The cooling tubes 40 pass through the grommets 62 and 63. In this way, the cooling tubes 40 pass through the grommets 62 and 63 and are led outside the wire harness unit 10, thus enabling deterioration in the water sealing performance of the wire harness unit 10 to be suppressed.

### Example Modifications

The present embodiment can be implemented in a modified manner as follows. The present embodiment and the following example modifications can be implemented in combination with each other to the extent that there are no technical inconsistencies.

For example, on the supply side of the cooling medium 41 with respect to the wire harness unit 10, branched distal end portions of one Y-shaped cooling tube may be connected to the two cooling tubes 40 shown in FIG. 3, and the cooling medium 41 that is supplied from the one cooling tube may be branched into the two cooling tubes 40. The branched portion of the cooling tube can be disposed outside the grommet 62 or can be disposed inside the grommet 62. By adopting this configuration, one cooling tube need only be connected to the wire harness unit 10 in order to supply the cooling medium 41, and the attachment process to the wire harness unit 10 can be simplified.

Also, on the discharge side of the cooling medium 41 with respect to the wire harness unit 10, branched distal end portions of one Y-shaped cooling tube are connected to the two cooling tubes 40 and the cooling media 41 in both cooling tubes 40 are merged. The merged portion of the cooling tube can be disposed outside the grommet 63 or can be disposed inside the grommet 63. By adopting this configuration, one cooling tube need only be connected to the wire harness unit 10 in order to discharge the cooling medium 41, and the attachment process to the wire harness unit 10 can be simplified.

In the above embodiment, the cooling tubes 40 are led out through the grommets 62 and 63, that is, the cooling tubes 40 pass through the grommets 62 and 63, but the cooling tubes 40 may be led out through the connectors 71 and 72. By adopting this configuration, the tubular conductor 21 and the connectors 71 and 72 can be cooled.

The electromagnetic shielding member 50 of the above embodiment may be a metal tape or the like. An insulating layer may be provided on the inner peripheral surface of the electromagnetic shielding member 50.

In the above embodiment, a wire harness unit including one or three or more conduction paths may be provided.

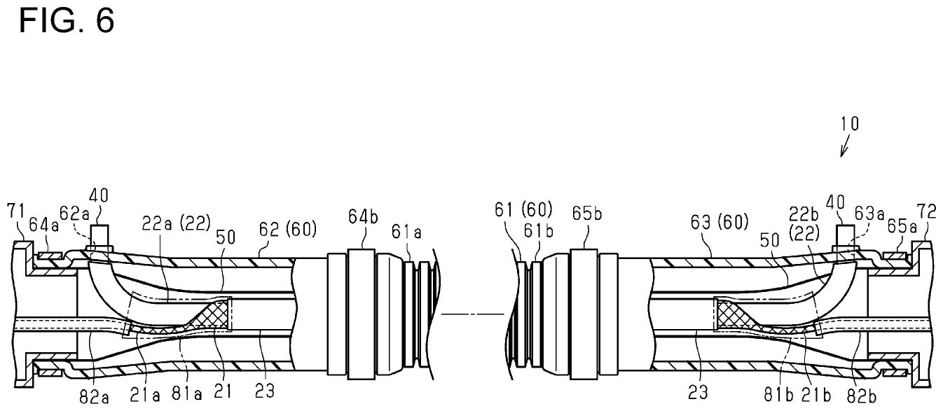

As shown in FIG. 6, a configuration may be adopted in which covering members 81a and 81b (covers) that cover the exposed portions 21a and 21b of the tubular conductor 21 are provided. The covering members 81a and 81b have insulating properties and prevent contact between the exposed portions 21a and 21b and the electromagnetic shielding member 50. The covering members 81a and 81b are heat shrink tubing, for example. Also, a configuration may be adopted in which covering members 82a and 82b that cover the exposed portions 21a and 21b extending toward the connectors 71 and 72 are provided. The covering members 82a and 82b are heat shrink tubing, for example. The covering members 82a and 82b are preferably constituted to cover to the terminals 25 and 26 shown in FIG. 5.

As shown in FIG. 6, the first insulating layer 22 covers the cooling tube 40 and passes through the electromagnetic shielding member 50. In this case, contact between the electromagnetic shielding member 50 and the cooling tube 40 can be prevented by the first insulating layer 22.

As shown in FIG. 4, the outer peripheral surface of the first insulating layer 22 may be in intimate contact with the inner peripheral surface of the tubular conductor 21 around the entire circumference. The inner peripheral surface of the second insulating layer 23 may be in intimate contact with the outer peripheral surface of the tubular conductor 21 around the entire circumference. The tubular conductor 21 may be referred to as a conductor layer, the first insulating layer 22 may be referred to as an inner insulating layer, and the second insulating layer 23 may be referred to as an outer insulating layer. Also, the conduction path 20 may be referred to as a multilayer tube or a conduction tube.

As shown in FIGS. 3 and 4, the cooling tube 40 that is separate from the multilayer tube may be inserted into the multilayer tube in the length direction of the multilayer tube. The cooling tube 40 may be disposed coaxially with the multilayer tube. The outer peripheral surface 40a of the cooling tube 40 may be in intimate contact with the inner peripheral surface 22c of the first insulating layer 22 around the entire circumference. The entire internal space of the cooling tube 40 may be a circulation channel for refrigerant, without any other members being disposed in the cooling tube 40.

As shown in FIGS. 3 and 4, a plurality of conduction paths 20 may be arranged in parallel to each other. The plurality of conduction paths 20 may be covered by one electromagnetic shielding member 50. The electromagnetic shielding member 50 may cover the plurality of conduction paths 20 with a gap between the electromagnetic shielding member 50 and the plurality of conduction paths 20.

As shown in FIGS. 3 and 4, the exterior member 60 may cover the plurality of conduction paths 20 and the electromagnetic shielding member 50 with a gap between the exterior member 60 and the plurality of conduction paths 20 and electromagnetic shielding member 50.

As shown in FIG. 3, the two end portions of the cooling tube 40 may respectively pass radially through the two end portions of the electromagnetic shielding member 50. Also, the two end portions of the cooling tube 40 may respectively pass radially through the grommets 62 and 63. As shown in FIG. 6, the exposed portions 22a and 22b may respectively pass radially through the two end portions of the electromagnetic shielding member 50, together with the two end portions of the cooling tube 40 respectively passing radially through the two end portions of the electromagnetic shielding member 50.

The present disclosure encompasses the following implementation examples. The reference numerals of a number of the constituent elements of the illustrative embodiment have been given not for limitation purposes but to aid understanding. Some of the matters described in the following implementation examples may be omitted, and a number of matters described in the implementation examples may be selected or extracted and combined.

### Supplementary Note 1

A wire harness unit (10) according to a number of modes of the present disclosure may include:

a multilayer tube (20) that conducts electricity; and

a cooling tube (40) that is configured to circulate a refrigerant therethrough and is separate from the multilayer tube (20),

the multilayer tube (20) may include:

a tubular conductor layer (21); and

an inner insulating layer (22) covering an inner peripheral surface of the conductor layer (21), and

the cooling tube (40) may be inserted into the multilayer tube (20) in a length direction of the multilayer tube (20).

### Supplementary Note 2

In one mode of the present disclosure, the cooling tube (40) may be disposed coaxially with the multilayer tube.

### Supplementary Note 3

In one mode of the present disclosure, an outer peripheral surface (40a) of the cooling tube (40) may be in intimate contact with an inner peripheral surface (22c) of the inner insulating layer (22) around an entire circumference.

### Supplementary Note 4

In one mode of the present disclosure, an entire internal space of the cooling tube (40) may be a circulation channel for the refrigerant.

### Supplementary Note 5

In one mode of the present disclosure, an outer peripheral surface of the inner insulating layer (22) may be in intimate contact with an inner peripheral surface of the conductor layer (21) around an entire circumference.

### Supplementary Note 6

In one mode of the present disclosure, the multilayer tube (20) may further have an outer insulating layer (23) covering an outer peripheral surface of the conductor layer (21), and

an outer peripheral surface of the outer insulating layer (23) may be in intimate contact with the outer peripheral surface of the conductor layer (21) around an entire circumference.

### Supplementary Note 7

The wire harness unit (10) according to a number of modes of the present disclosure may further include:

a plurality of the multilayer tube (20) arranged in parallel to each other; and

one electromagnetic shielding member (50) covering the plurality of multilayer tubes (20).

### Supplementary Note 8

The wire harness unit (10) according to one mode of the present disclosure may further include:

an electromagnetic shielding member (50) covering the multilayer tube (20) with a gap between the electromagnetic shielding member and the multilayer tube (20).

### Supplementary Note 9

The wire harness unit (10) according to one mode of the present disclosure may further include:

an exterior member (60) covering the electromagnetic shielding member (50) with a gap between the exterior member and the electromagnetic shielding member (50).

1. A wire harness unit comprising:
a conduction path that conducts electricity between in-vehicle devices; and
a cooling tube that cools the conduction path, wherein:
the conduction path has a hollow tubular conductor having conductivity, and a first insulating layer covered by the tubular conductor,
the cooling tube is configured to circulate a refrigerant therethrough and is separate from the tubular conductor, and
the cooling tube passes through the first insulating layer.

2. The wire harness unit according to claim 1,
wherein the tubular conductor is a first braided member formed by braiding metal wire strands.

3. The wire harness unit according to claim 1, comprising:
an electromagnetic shield covering the cooling tube and the conduction path, wherein:
the electromagnetic shield is a second braided member formed by braiding metal wire strands,
the first insulating layer has a first exposed portion exposed from the tubular conductor,
the first exposed portion covers the cooling tube, and
the cooling tube passes through the second braided member.

4. The wire harness unit according to claim 1, comprising:
an electromagnetic shield covering the cooling tube and the conduction path, wherein:
the electromagnetic shield is a second braided member formed by braiding metal wire strands,
the first insulating layer has a first exposed portion exposed from the tubular conductor,
the first exposed portion covers the cooling tube, and
the first exposed portion and the cooling tube pass through the second braided member.

5. The wire harness unit according to claim 3, wherein:
the conduction path has a terminal and a second insulating layer covering an outer peripheral surface of the tubular conductor,
the tubular conductor has a second exposed portion exposed from the second insulating layer,
the second exposed portion is electrically connected to the terminal, and
the second exposed portion branches away from the first exposed portion and is covered by the electromagnetic shield.

6. The wire harness unit according to claim 5, comprising:
a cover that covers the second exposed portion.

7. The wire harness unit according to claim 1, comprising:
an exterior cover that covers the conduction path, wherein:
the exterior cover has a tubular exterior and a grommet connected to an end of the tubular exterior, and
the cooling tube passes through the grommet.
